(19) United States
(12) Patent Application Publication
(10) Pub. No.: US 2025/0362590 A1
(43) Pub. Date: Nov. 27, 2025

(54) METHODS OF REPAIRING EXTREME ULTRAVIOLET PHOTOMASKS

(71) Applicant: Taiwan Semiconductor Manufacturing Co., Ltd., Hsinchu (TW)

(72) Inventors: Ying-Hui HSIEH, Hsinchu (TW); Po-Ming HSU, Hsinchu (TW); Hsiang-Chien HSU, Hsinchu (TW); Chien-Hung LAI, Hsinchu (TW)

(73) Assignee: Taiwan Semiconductor Manufacturing Co., Ltd., Hsinchu (TW)

(21) Appl. No.: 19/294,066

(22) Filed: Aug. 7, 2025

Related U.S. Application Data
(63) Continuation of application No. 18/611,138, filed on Mar. 20, 2024.
(60) Provisional application No. 63/591,335, filed on Oct. 18, 2023.

(51) Int. Cl. G03F 1/72; C07F 15/00; C23C 16/48; G03F 1/24; G03F 1/54

(52) U.S. Cl. CPC G03F 1/72; C07F 15/0053; C23C 16/487; G03F 1/24; G03F 1/54

(57) ABSTRACT

A method for repairing a lithography mask is provided. The method includes receiving a lithography mask having a capping layer that includes a damaged region, identifying a location and a dimension of the damaged region of the capping layer, determining a repairing time duration based on the dimension of the damaged region of the capping layer, and forming a capping patch layer in the damaged region of the capping layer.

### PRIORITY CLAIM AND CROSS-REFERENCE

This application is a Continuation of U.S. application Ser. No. 18/611,138, filed Mar. 20, 2024, which claims the benefit of U.S. Provisional Patent Application No. 63/591,335, filed Oct. 18, 2023, each of which is incorporated by reference herein in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs. Such scaling down has also increased the complexity of processing and manufacturing ICs and, for these advances to be realized, similar developments in IC processing and manufacturing are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an extreme ultraviolet (EUV) photomask, in accordance with some embodiments.

FIGS. 2A-2D are cross-sections views of the EUV photomask of FIG. 1 having various defects, in accordance with some embodiments.

FIG. 3 is a flowchart of a method for repairing a damaged capping layer of a EUV mask, in accordance with some embodiments.

FIG. 4A-7 are various views of an EUV photomask at various repairing stages of the method of FIG. 3, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

When fabricating integrated circuits, photolithography is often used to form various features such as metal lines into a semiconductor substrate. To form these features, a photomask is used to form a pattern into a photoresist layer. The regions where the photoresist layer is removed expose the underlying substrate to an etching process used to form trenches where metal is subsequently placed.

One type of photolithography is extreme ultraviolet (EUV) lithography using an EUV photomask. In one example of an EUV photomask, a patterned absorber layer is formed on a reflective multilayer stack. To expose a photoresist layer on a semiconductor substrate, EUV light is projected onto the photomask through a number of mirrors. The exposed portions of reflective multilayer stack then reflect light onto the semiconductor substrate on which an integrated circuit is to be formed. The light thus exposes a photoresist layer deposited on that semiconductor substrate.

The reflective multilayer EUV photomask architectures are highly susceptible to surface oxidation and contamination. As a result, EUV photomasks will require periodic cleaning to mitigate defectivity-—as many as twenty times or more to meet high volume manufacturing (HVM) lifetime goals. An EUV photomask typically includes a capping layer between the reflective multilayer stack and the absorber layer. The capping layer protects the reflective multilayer stack from any unexpected damages that might be caused during absorber layer etching, repair, and periodic cleaning. However, the capping layer is also subject to damage and may be worn out over time with repeated use. For example, the EUV photomask is generally cleaned after a certain number of uses. During the cleaning, the acid and chemicals can penetrate into the capping layer, causing damage to the capping layer. Damage to the capping layer degrades EUV reflectivity that can lead to critical dimension (CD) shift and non-uniformity. Such damaged EUV photomask needs to be scrapped to ensure the quality of ICs if the capping layer suffering from serious damages is not repaired.

In embodiments of the present disclosure, the damaged capping layer is repaired by first identifying the location and dimension of a damaged region in the capping layer using images obtained from a scanning electron microscopy (SEM) tool and an atomic force microscopy (AFM) tool. A repairing time duration is then calculated based on the remaining thickness of the capping layer in the damaged region and the area of the damaged region. Additional capping material is then deposited in the damaged region of the capping layer using a focused electron beam in combination with a Ru complex-containing precursor gas. The repairing methods of the present disclosure enables quick repair of the damaged capping layer. Consequently, the lifespan of the EUV photomask can be extended, leading to a reduction in the overall cost of the EUV photomask.

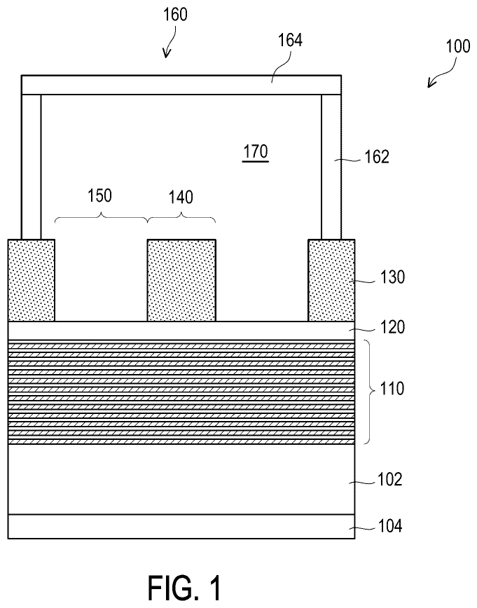

FIG. 1 is a cross-sectional view of an EUV photomask 100 used in EUV lithography, in accordance with various embodiment of the present disclosure.

The EUV photomask 100 includes a substrate 102. The substrate 102 is chosen to minimize image distortion due to mask heating by the intensified illumination radiation. The substrate 102 includes materials with a low defect level and a smooth surface. In some embodiments, the substrate 102 includes a low thermal expansion material (LTEM). The LTEM may include fused silica, calcium fluoride, silicon carbide, black diamond, titanium oxide doped silicon oxide (SiO₂/TiO₂), or other suitable LTEMs. Alternatively, the substrate 102 includes other materials, such as quartz, fused quartz, or glass, depending on design requirements of the mask. In some embodiments, the substrate 102 has a thickness ranging from about 1 mm to about 7 mm. If the thickness of the substrate 102 is too small, a risk of breakage or warping of the EUV photomask 100 increases, in some instances. On the other hand, if the thickness of the substrate is too great, a weight of the EUV photomask 100 is needlessly increased, in some instances

In addition, a conductive layer 104 may be formed on the backside surface of the substrate 102 for the electrostatic chucking purposes. In some embodiments, the conductive layer 104 includes chromium nitride (CrN), tantalum boride (TaB), or other suitable conductive material. In some embodiments, the conductive layer 104 is formed by a deposition process such as, for example, chemical vapor deposition (CVD), plasma-enhanced chemical vapor deposition (PECVD), or physical vapor deposition (PVD). The thickness of the conductive layer 104 is controlled such that the conductive layer 104 is optically transparent.

The EUV photomask 100 includes a reflective multilayer stack 110 (also referred to as a multilayer mirror (MLM)) disposed over the substrate 102 on the front surface (i.e., opposite the surface on which the conductive layer 104 is formed). The reflective multilayer stack 110 is designed to reflect of the radiation light directed to the substrate 102. In some embodiments, the reflective multilayer stack 110 includes alternating layers of two materials deposited on the top of the substrate 102 to act as a Bragg reflector that maximizes the reflection of the radiation light, such as EUV light with 13.5 nm wavelength. In some embodiments, the reflective multilayer stack 110 is configured to achieve about 60% to about 75% reflectivity at the peak EUV radiation wavelength.

The combination of the two materials in the alternating layers selected to provide a large difference in refractive indices between the two layers (for example, to achieve large reflectivity at an interface of the two layers according to Fresnel equations), yet provide small extinction coefficients for the layers (for example, to minimize absorption). In some embodiments, the reflective multilayer stack 110 includes molybdenum-silicon (Mo/Si) layer pairs with a layer of molybdenum above or below a layer of silicon in each layer pair. In some embodiments, the reflective multilayer stack 110 includes molybdenum-beryllium (Mo/Be) layer pairs with a layer of molybdenum above or below a layer of beryllium in each layer pair. A thickness of each layer of each layer pair in the reflective multilayer stack 110 is adjusted depending on a wavelength and an angle of incidence of light (such as EUV radiation) incident on the mask, such that the mask achieves maximum constructive interference of light reflected from different interfaces of the reflective multilayer stack 110. In general, reflectivity of the reflective multilayer stack 110 increases as a number of layer pairs in the reflective multilayer stack 110 increases. Accordingly, in principle, if the number of layer pairs is sufficiently large and extinction coefficients of the materials of the layers are close to zero, the reflectivity of the reflective multilayer stack 110 can approach 100% regardless of the difference of the refractive indices of the materials of the layers in the layer pairs. However, in the EUV wavelength range, the highest reflectivity that can be achieved is limited by the extinction coefficients of the materials employed for the layers in the reflective multilayer stack 110. In some embodiments, the number of layer pairs in the reflective multilayer stack 110 is from 20 to 80. For example, in the depicted embodiment, to achieve more than 90% of the maximum achievable reflectivity (with the chosen materials) of the reflective multilayer stack 110 and minimize mask blank manufacturing time and costs, the reflective multilayer stack 110 includes about 40 layer pairs, such as 40 Mo/Si pairs. In furtherance of the example, the Mo/Si pairs includes a silicon layer having a thickness of 3 nm to 5 nm (for example, about 4 nm); and a molybdenum layer having a thickness of 2 nm to 4 nm (for example, about 3 nm). Alternatively, the reflective multilayer stack 110 includes any other number of layer pairs, depending on reflectivity specifications for the mask. In other alternatives, the reflective multilayer stack 110 may include layer groups, in other words, groups of three or more layers having different refractive indices and other characteristics to maximize reflectivity

In the present example, the reflective multilayer stack 110 includes molybdenum-silicon (Mo/Si) layer pairs. The reflective multilayer stack 110 includes about 40 (Mo/Si) layer pairs and each Mo/Si layer pair has a collective thickness of about 7 nm.

In some embodiments, each layer in the reflective multilayer stack 110 is deposited over the substrate 102 and underlying layer using ion beam deposition or DC magnetron sputtering. The deposition method used helps to ensure the thickness uniformity of the reflective multilayer stack 110 is better than about 0.85 across the substrate 102. For example, to form a Mo/Si reflective multilayer stack 110, a Mo layer is deposited using a Mo target as the sputtering target and an argon (Ar) gas (having a gas pressure of from 1.3×10⁻² Pa to 2.7×10⁻² Pa) as the sputtering gas with an ion acceleration voltage of from 300 V to 1,500 V at a deposition rate of from 0.03 to 0.30 nm/sec and then a Si layer is deposited using a Si target as the sputtering target and an Ar gas (having a gas pressure of 1.3×10⁻² Pa to 2.7×10⁻² Pa) as the sputtering gas, with an ion acceleration voltage of from 300 V to 1,500 V at a deposition rate of from 0.03 to 0.30 nm/sec. By stacking Si layers and Mo layers in 40 to 50 cycles, each of the cycles comprising the above steps, the Mo/Si reflective multilayer stack is deposited.

The EUV photomask 100 includes a capping layer 120 deposited on the reflective multilayer stack 110. Because the capping layer 120 has different etching characteristics from an absorber layer, the capping layer 120 provides a protection to the reflective multilayer stack 110, such as an etch stop layer in a subsequent patterning of the absorber layer or a repairing process of the EUV photomask 100. Furthermore, the same capping layer 120 is also designed to function as an anti-oxidation barrier layer to protect the reflective multilayer stack 110 from oxidation. At the same time, the capping layer 120 will not degrade the EUV reflectivity from the reflective multilayer stack 110. The capping layer 120 may include ruthenium (Ru) or a Ru-based compound. In some embodiments, the Ru-based compound may contain one or more elements such as niobium (Nb), tantalum (Ta), zirconium (Zr), boron (B), nitrogen (N), or oxygen (O). In some embodiments, the Ru-based compound may include, RuO₂, RuNb, RuNbO, RuON, RuN, RuNbON, RuTaON, RuZr, RuZrO, or RuB. In some embodiments, the Ru-containing compound is RuNb, with the atomic weight of the Nb being less than or equal to 50 atomic (at)%, for example at about 10 atomic %, 20 atomic %, 30 atomic %, or 40 atomic %.

The capping layer 120 has a thickness that is thick enough to provide anti-oxidation and etching resistance to the reflective multilayer stack 110 underneath, but not too thick to degrade the EUV reflectivity of reflective multilayer stack 110. In some embodiments, the capping layer 120 may have a thickness ranging from 1 nm to 10 nm. In some embodiments, the capping layer 120 has a thickness ranging from 2 nm to 4 nm. In some embodiments, the capping layer 120 has a thickness about 2.5 nm.

In some embodiments, the capping layer 120 is formed using a deposition process such as, for example, ion beam deposition, chemical vapor deposition (CVD), physical vapor deposition (PVD) such as DC magnetron sputtering, or atomic layer deposition (ALD). In instances where a Ru layer is to be formed as the capping layer 120 using ion beam deposition, the deposition may be carried out in an Ar atmosphere by using a Ru target as the sputtering target. In some embodiments, the capping layer 120 thus formed may have a polycrystalline structure with multiple grains of varying sizes and orientations. Alternatively, the capping layer 120 is formed as an amorphous layer.

The EUV photomask 100 also includes a patterned absorber layer 130 formed on the capping layer 120. The patterned absorber layer 130 is designed to absorb radiation light (such as EUV light) during a lithography exposing process. The radiation light passes through the openings of the patterned absorber layer 130 and is reflected by the reflective multilayer stack 110, thus the IC pattern is imaged to an IC substrate, such as a silicon wafer. In some embodiments, the patterned absorber layer 130 includes chromium (Cr), chromium oxide (CrO), titanium nitride (TiN), tantalum nitride (TaN), tantalum (Ta), titanium (Ti), aluminum-copper (Al-Cu), palladium (Pd), tantalum boron nitride (TaBN), tantalum boron oxide (TaBO), aluminum oxide (Al₂O₃), silver oxide (Ag₂O), or other suitable materials. In yet another embodiment, the patterned absorber layer 130 includes multiple layers.

The patterned absorber layer 130 includes features that define an IC pattern thercon, such as according to an IC layout pattern. For example, as shown in FIG. 1, the patterned absorber layer 130 defines opaque regions 140 and reflective regions 150. In the opaque region 140, the absorber layer remains on the EUV photomask 100 while in the reflective region 150, the absorber layer is removed.

Still referring to FIG. 1, in some embodiment, a pellicle 160 may be positioned over the EUV photomask 100 to protect the pattern side of the EUV photomask 100 from contamination during storage, use or transport. The pellicle 160 and the EUV photomask 100 may form an enclosed inner space 170 that is enclosed by the pellicle 160 and the EUV photomask 100. The patterned surface of the EUV photomask 100 is enclosed in the inner space 170 and is therefore protected from contamination during a lithography patterning process, masking shipping, and mask handling In some embodiments, the pellicle 160 includes a pellicle frame 162 that may be positioned over the patterned absorber layer 130. In some embodiments, the pellicle frame 162 may be formed from Si, SiC, SiN, glass, a low coefficient of thermal expansion material (such as an Al alloy, a Ti alloy, Invar, Kovar, or the like), another suitable material, or a combination thereof. In some embodiments, suitable processes for forming the pellicle frame 162 may include machining processes, sintering processes, photochemical etching processes, other applicable processes, or a combination thereof. The pellicle 160 may further includes a pellicle membrane 164 positioned attached to the pellicle frame 162 via adhesive. The pellicle membrane 164 is a thin film transparent to the radiation beam used in a lithography patterning process, and furthermore has a thermal conductive surface. In some embodiments, the pellicle membrane 164 may include silicon, such as polycrystalline silicon (poly-Si), amorphous silicon (a-Si), doped silicon (such as phosphorous doped silicon SiP or SiC) or a silicon-based compound, such as SiN or MoSixNy or combination (SiN/MoSiN). Alternatively, the pellicle membrane 164 may include polymer, graphene, carbon network membrane, carbon nanotubes, silicon carbon nanotube, boron nitride nanotube, carbon nanotube bundles or other suitable material, including bundles of nanotubes. The pellicle membrane 164 has a thickness with enough mechanical strength, but in some embodiments, not a thickness that degrades the transparency of the membrane to EUV radiation from the radiation source by more than 15% in some embodiments, more than 10% in some embodiments or more than 5% in some embodiments. In some examples, the pellicle membrane 164 has a thickness ranging between 30 nm and 50 nm.

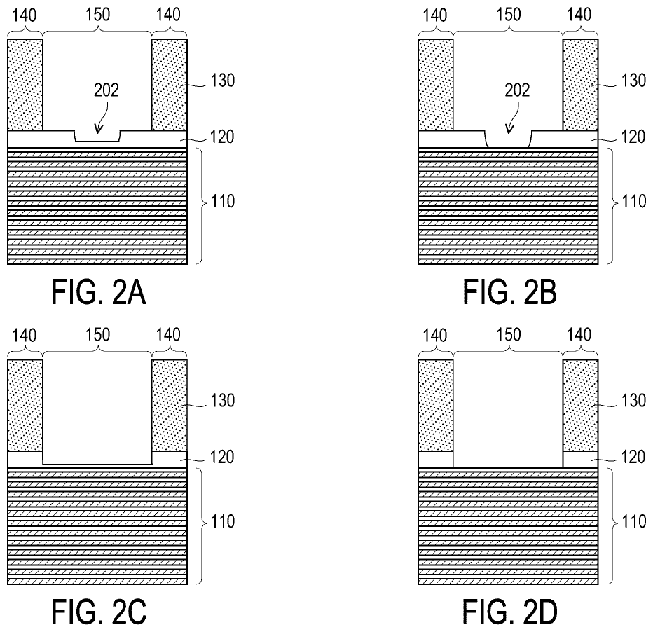

As described above, the capping layer 120 of the EUV photomask 100 is subject to damage. FIGS. 2A-2D illustrates various types of damage to the capping layer 120 of the EUV photomask 100, in accordance with some embodiments of the present disclosure. For instance, aggressive cleaning methods such as Megasonic process can result in a partial loss of the capping material or peeling of the capping layer 120, creating a pit 202 in the capping layer 120, as depicted in FIG. 2A. Over time, this pit 202 may expend, ultimately causing a complete loss of the capping material within the pit 202, thereby exposing the reflective multilayer stack 110 underneath, as shown in FIG. 2B. Additionally, with repeated use, the capping layer 120 may be etched during the cleaning processes, leading to gradual thinning of the capping layer 120 over time, as shown in FIG. 2C. Furthermore, prolonged use and repeated cleaning processes may result in complete worn out of the capping layer 120 in the reflective region 150. As illustrated in FIG. 2D, over a certain period, the capping layer 120 in the reflective region 150 of the EUV photomask 100 may undergo complete removal. As a result, the surface of the reflective multilayer stack 110 is no longer protected by the capping layer 120. All these types of damage shown in FIGS. 2A-2D may lead to the deterioration of the reflective multilayer stack 110, and an EUV reflectivity loss.

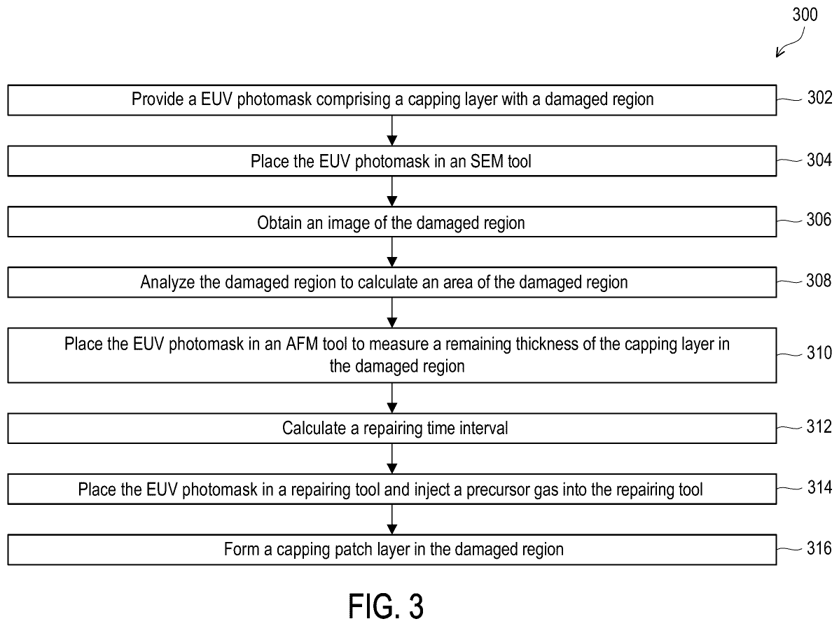

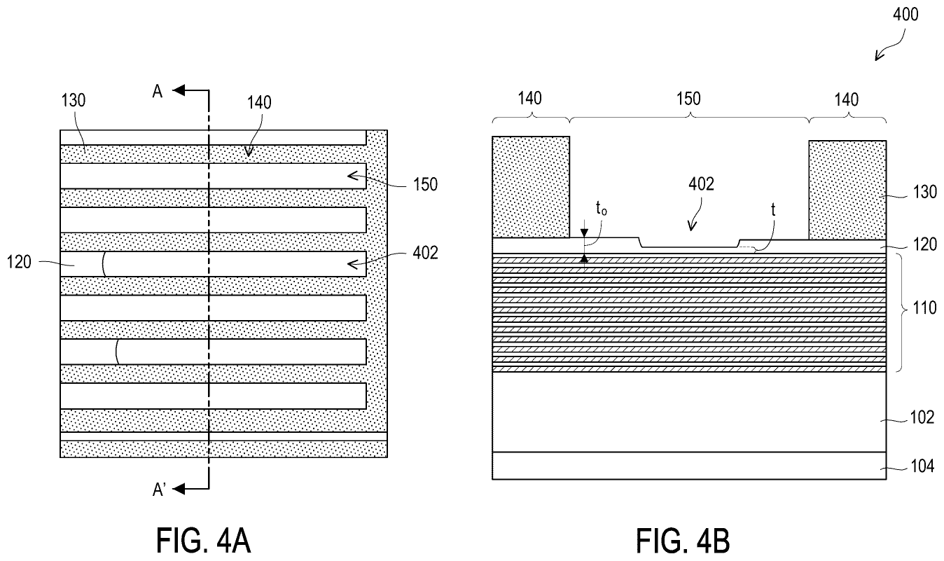

FIG. 3 is a flowchart of a method 300 for repairing a capping layer 120 of a photomask 400, in accordance with some embodiments of the present disclosure. Additional operations can be provided before, during, and after the method 300, and some operations described can be replaced, eliminated, or relocated for additional embodiments of the method. The method 300 is an example, and is not intended to limit the present disclosure beyond what is explicitly recited in the claims. The method 300 is described below in conjunction with FIGS. 4A-7. FIG. 4A-7 are various views of an EUV photomask 400 at various repairing stages of the method 300.

Referring to FIGS. 3 and 4A-4B, the method 300 starts at operation 302 by providing an EUV photomask 400 having a capping layer 120 that needs to be repaired, in accordance with some embodiments. FIG. 4A is a top view of the EUV photomask 400, in accordance with some embodiments. FIG. 4B is a cross-sectional view of the EUV photomask 400 of FIG. 4A along line A-A′. As shown in FIG. 4A, the capping layer 120 contains damaged regions 402 situated in the reflective regions 150 of the EUV photomask 400. As shown in FIG. 4B, within the damaged region 402, the capping material is lost, creating a pit in the capping layer 120. The damaged region 402 thus is also referred to as a capping material loss region.

Referring to FIG. 3, the method 300 proceeds to operation 304, where the EUV photomask 400 is placed into a first mask inspection tool, in accordance with some embodiments. In some embodiments, the first mask inspection tool is a scanning electron microscope (SEM) tool. The pressure of the SEM tool may be controlled ranging from 1×10⁻⁶ mbar to 1×10⁻⁷ mbar.

Referring to FIG. 3, the method 300 proceeds to operation 306, where the EUV photomask 400 is inspected to identify a damaged region 402 using the first mask inspection tool, in accordance with some embodiments. In some embodiments, inspecting the EUV photomask 400 includes scanning a surface of the capping layer 120 using a tip of the first mask inspection tool to obtain an image of the damaged region 402. After the scanned image is obtained, the scanned image is input into an algorithm. Further at operation 306, the position of the damaged region 402 may be recorded by coordinates in a grid based on distances away from edges of the scanned image. The coordinates of the damaged regions 402 may be expressed as (x value, y value).

Referring to FIG. 3, the method 300 proceeds to operation 308, where the scanned image is analyzed in accordance with some embodiments. In some embodiments, the scanned image is analyzed using, for example, an image processor, to determine the size, i.e., length and width, of the damaged region 402. The area of the damaged region 402 is then calculated based on the size of the damaged region 402.

Referring to FIG. 3, the method 300 proceeds to operation 310, where the EUV photomask 400 is placed in a second inspection tool and a remaining thickness (t) of the capping layer 120 in the damaged region 402 is measured using the second inspection tool, in accordance with some embodiments. In some embodiments, the second inspection tool is an atomic force microscopy (AFM) tool. The AFM input thus can be used to determine the deposition height in the repairing deposition process subsequently performed. In some embodiments, operation 310 may be performed before operation 308.

Referring to FIG. 3, the method 300 proceeds to operation 312, where a repairing time duration (i.e., a required deposition time) is calculated based on the remaining thickness of the capping layer 120 in the damaged region 402 and the area of the damaged region 402, in accordance with some embodiments.

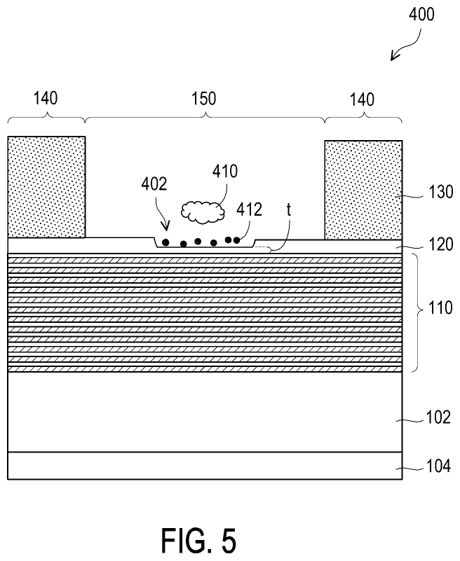

Referring to FIGS. 3 and 5, the method 300 proceeds to operation 314, where the EUV photomask 400 is placed in a mask repair tool, in accordance with some embodiments. In some embodiments, the mask repair tool is an electron-beam (E-beam) based mask repair tool in which an electron beam column is combined with a gas injection system. Operation 314 further includes injecting a precursor gas 410 comprising a metal complex into the mask repair tool via the gas injection system. In some embodiments, the mask repair tool is an SEM tool. In some embodiments, the mask inspection or repairing operations may be performed by the same tool. In some embodiments, the precursor gas 410 further includes a reaction gas containing ammonia (NH3) or nitrous oxide (N₂O).

In the mask repair tool, clements of the precursor gas 410 are absorbed to the surface of the capping layer 120 and further spread out in the damaged region 402 of the capping layer 120. FIG. 5 is a cross-sectional view of the EUV photomask 400 after the elements 412 of the precursor gas 410 are absorbed onto the surface of the capping layer 120 in the damaged region 402, in according with some embodiments.

In embodiments of the present disclosure, the flow rate of the precursor gas 410 is selected to ensure that the repair of the EUV photomask 400 is completed within the repairing time duration as well as to facilitate the volume repairing of the EUV photomask 400. For example, in some embodiments, the flow rate of the precursor gas 410 may be selected in a range from 10,000 to 100,000 standard cubic centimeters per minute (sccm). In some embodiments, the flow rate of the precursor gas 410 may range from 1 to 100,000 sccm. A higher pressure of the precursor gas 410 in the SEM tool generally leads to faster deposition of the metal complex, and a higher flow rate of the precursor gas 410 generally leads to a higher pressure thereof.

In some embodiments, the metal complex comprises a Ru complex having the following chemical formula:

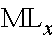

wherein:
M is Ru;
x is an integer of 1 to 6; and
L is, at each occurrence, independently an acetylacetonate, alkylcyclopentadienyl, benzene, carbonyl, cyclopentadienyl, cycloyhexadiene, fluorinated amino alcohol, pentadienyl, pyrrolyl, trifluoroalkyl or halogen ligand, derivatives thereof, or combinations thereof.
x is the coordination number indicating the number of places on the Ru ion where ligands, L, are bound. In some embodiments, x is 2. In some embodiments, x is 3. In some embodiments, x is 4. In some embodiments, x is 5. In some embodiments, x is 6.

In some embodiments, the Ru complex has one of the following structures:

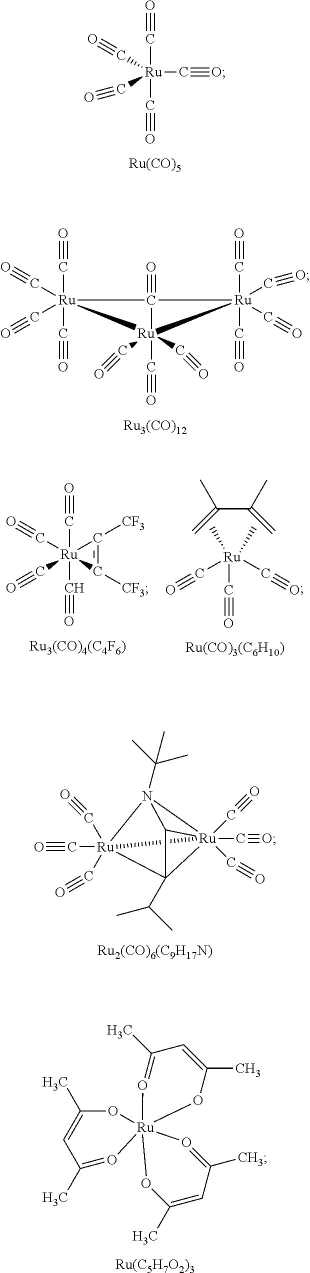

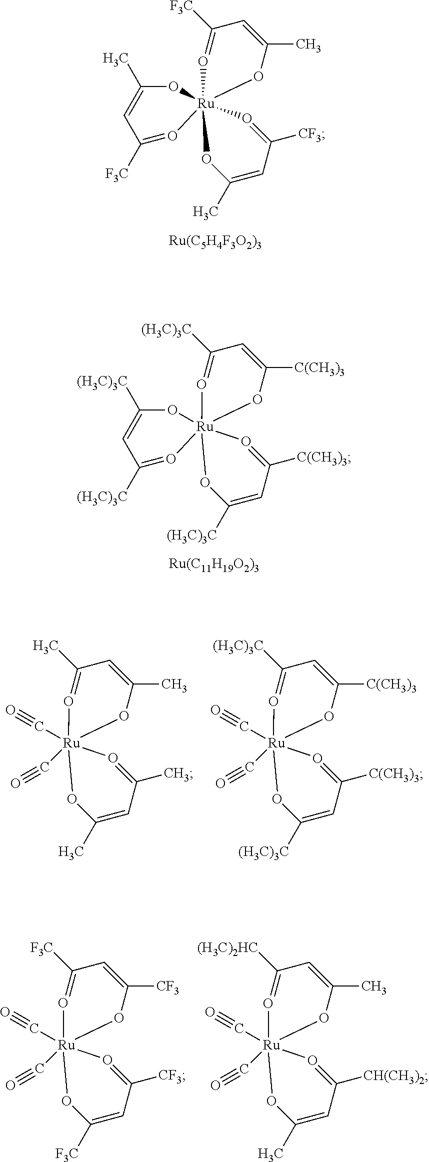

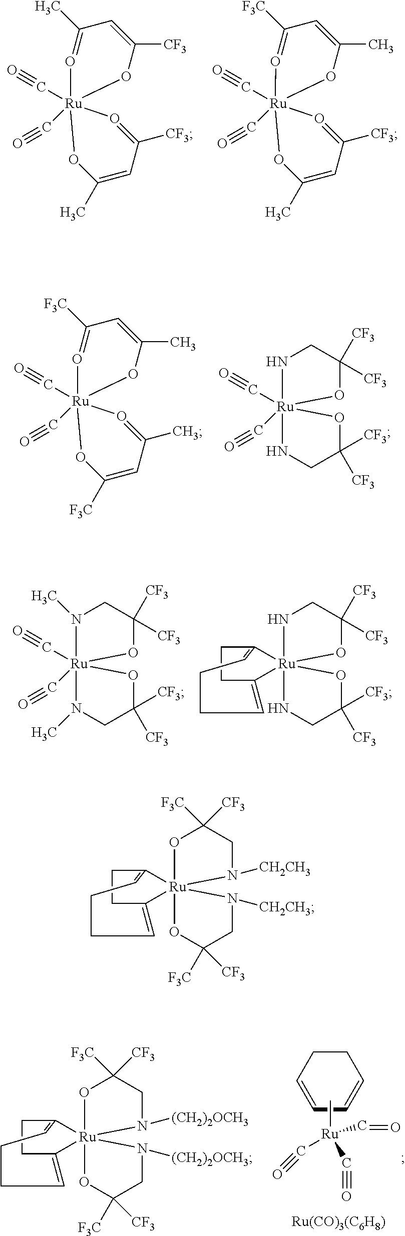

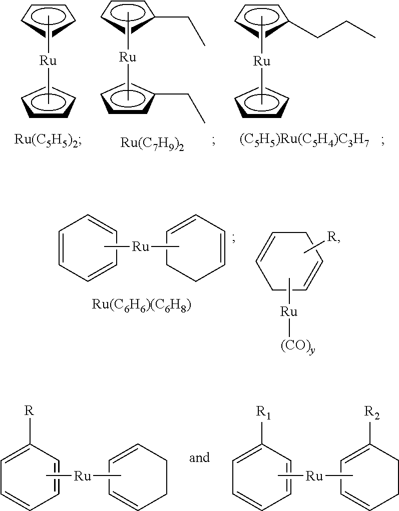

wherein:
R, R₁ and R₂ are each independently alkyl or alkoxy; and
y is an integer from 1 to 5.

In some embodiments, R, R₁ and R₂ are each independently methyl, ethyl, butyl, or hexyl.

In some embodiments, R, R₁ and R₂ are each independently methoxy, ethoxy, or 2-methoxyethyl.

In some embodiments, y is 2 or 3.

In some embodiments, the Ru complex has one of the following structures:

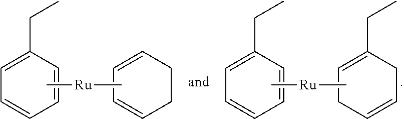

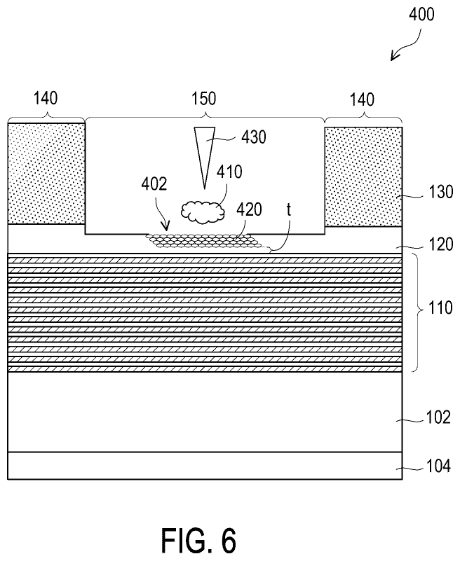

Referring to FIGS. 3 and 6, the method 300 proceeds to operation 316, where a local deposition is performed to repair the capping layer 120 by forming a capping patch layer 420 in the damaged region 402 of the capping layer 120, in accordance with some embodiments. FIG. 6 is a cross-sectional view of the EUV photomask 400 after forming the capping patch layer 420 in the damaged region 402 of the capping layer, in accordance with some embodiments.

As shown in FIG. 6, the precursor gas 410 and the capping layer 120 is irradiated with a focused radiation beam 430. The focused radiation beam 430 triggers a chemical reaction of the Ru-complex, and thus the Ru-containing compound can be deposited in the damaged region 402 of the capping layer 120. In some embodiments, the focused radiation beam 430 is a highly energetic radiation such as an E-beam. When E-beam is used, the deposition of Ru-complex is also called E-beam induced deposition. In some embodiments, the focused radiation beam 430 is a laser beam. The capping layer 120 absorbs some of the energy of the radiation beam 430, thereby generating secondary electrons.

As only damaged region 402 of the capping layer 120 is irradiated by the radiation beam 430 and, in this damaged region 402, so deposited the Ru-containing compound. A shape of the resulting capping patch layer 420 corresponds to the damaged region 402 in the capping layer.

A voltage of the radiation beam 430 is used to limit charging of the surface of the EUV photomask 400. In some embodiments, a voltage of the radiation beam 430 to deposit the capping patch layer 420 is in the approximate range of 0.4 kilovolts (kV) to 3 kV, for example, about 1 kV. Typically, higher voltage of the radiation beam 430 provides higher spatial resolution. The radiation beam 430 dwells above the surface of the damaged region 402 for a predetermined time and then moves by a predetermined step, to the next point above the surface of the damaged region 402. The dwelling and moving of the radiation beam 430 is continuously repeated until the capping patch layer 420 having a predetermined thickness is formed in the damaged region 402. In some embodiments, the predetermined time for dwelling of the radiation beam 430 over one point of the surface of the damaged region 402 is in the approximate range of 0.05 μsec to 10 μsec, and the predetermined step to move the radiation beam 430 from one point to the next point along the surface of the damaged region 402 is in the approximate range of 1 nm to 10 nm. For an embodiment, the EUV photomask 400 may be positioned relative to the incident radiation beam 430 at any angle to allow the capping patch layer 420 be built at any angle and any orientation relative to the surface of the damaged region 402.

The capping patch layer 420 may include a capping material the same as or different from the material forming the capping layer 120. In some embodiments, the capping patch layer 420 includes a Ru-containing compound that is the same as the Ru-containing compound providing the capping layer 120. In some embodiments, the capping patch layer 420 includes a Ru-containing compound that is different from the Ru-containing compound providing the capping layer 120. In some embodiments, the capping patch layer 420 includes Ru or RuO₂. In some embodiments, the capping patch layer 420 includes an amorphous Ru-containing compound. In some embodiments, the capping patch layer 420 includes a crystalline Ru-containing compound. In the present embodiment as shown in FIG. 6, the capping patch layer 420 is embedded in the capping layer 120 such that a bottom surface of the capping patch layer 420 is in contact with the capping layer 120. In some embodiments, both of the capping layer 120 and the capping patch layer 420 are amorphous. In some embodiments, the capping layer 120 has a polycrystalline structure, while the capping patch layer 420 has an amorphous structure.

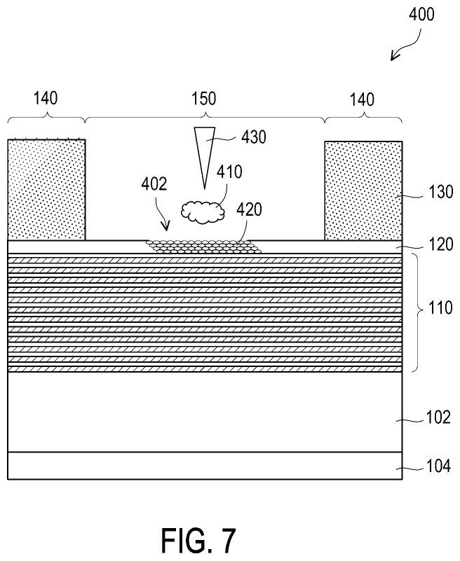

In instances where the capping material in the damaged region 402 is completely lost so that a top surface of the reflective multilayer stack 110 is exposed by the damaged region 402, the capping patch layer 420 formed in the damaged region 402 is in direct contact with the top surface of the reflective multilayer stack 110, as shown in FIG. 7.

After deposition of the capping patch layer 420, a cleaning process may be performed to clean the surface of the EUV photomask 400. In some embodiments, standard acid-based wet cleaning chemistries may be used to clean the surface of the EUV photomask 400. The process includes two steps: organic removal by a mixture of sulfuric acid and hydrogen peroxide (SPM) followed by particle cleaning by a SCI solution consisting of a mixture of NH₄OH (ammonium hydroxide), H₂O₂ (hydrogen peroxide) and H₂O with megasonics.

In some embodiments, once the EUV photomask repairing operation is completed, the method 300 loops back to operation 304 to perform another photomask inspection operation. The inspection operation is to ensure that the capping layer is successfully repaired. The iteration of operation 304 to 316 will continue until all of the damaged regions in the capping layer 120 are found and prepared.

Once the EUV photomask 400 has been repaired and cleaned, the EUV photomask 400 may be utilized to form patterns, e.g., structures on a semiconductor substrate (not shown). For example, the EUV photomask 400 may be placed into a lithography scanner. Once in place, the EUV photomask 400 may be illuminated by an energy source, with the patterned absorber layer 130 blocking portions of light to form a patterned light pattern. This patterned light may be focused and directed towards a photoresist on a semiconductor substrate, illuminating the photoresist in a desired pattern. Once illuminated, the photoresist may be developed and used as a mask for forming devices, metallization layers, isolation regions, and other structures on or within the semiconductor substrate.

One aspect of this description relates to a method for repairing a lithography mask. The method includes receiving a lithography mask having a capping layer, wherein the capping layer includes a damaged region, identifying a location and a dimension of the damaged region of the capping layer, determining a repairing time duration based on the dimension of the damaged region of the capping layer, and forming a capping patch layer in the damaged region of the capping layer.

Another aspect of this description relates to a lithography mask. The lithography mask includes a substrate, a reflective multilayer stack over the substrate, a capping layer over the reflective multilayer stack, and a patterned absorber layer over the capping layer, the patterned absorber layer defining a reflective region of the lithography mask. The capping layer includes an amorphous portion located in the reflective region of the lithography mask and surrounded by a polycrystalline portion. The polycrystalline portion includes a first ruthenium-containing material and the amorphous portion includes a second ruthenium-containing material.

Still another aspect of this description relates to a lithography mask. The lithography mask includes a substrate, a reflective multilayer stack over the substrate, a capping layer over the reflective multilayer stack, the capping layer including a ruthenium-containing material, a capping patch layer surrounded by the capping layer, the capping patch layer including an amorphous ruthenium-containing material, and a patterned absorber layer over the capping layer, the patterned absorber layer defining a reflective region of the lithography mask. The capping patch layer is in the reflective region of the lithography mask.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
obtaining an image of a surface of a capping layer of a lithography photomask by scanning the surface of the capping layer, the lithography photomask comprising:
a substrate;
a reflective multilayer stack over the substrate;
the capping layer over the reflective multilayer stack;
a patterned absorber layer over the capping layer,
wherein the capping layer includes a damaged region where at least a portion of the capping layer is lost;
analyzing the image to identify a location, a length and a width of the damaged region of the capping layer;
measuring a height of the capping layer remaining in the damaged region;
determining a repairing time duration based on the length and the width of the damaged region of the capping layer as well as the height of the capping layer remaining in the damaged region; and
depositing a capping patch layer in the damaged region of the capping layer.

2. The method of claim 1, wherein the capping layer comprises ruthenium (Ru) or a Ru-based compound.

3. The method of claim 2, the Ru-based compound may contain one or more elements such as niobium (Nb), tantalum (Ta), zirconium (Zr), boron (B), nitrogen (N) or oxygen (O).

4. The method of claim 3, wherein the capping layer comprises Ru, RuO₂, RuNb, RuNbO, RuON, RuN, RuNbON, RuTaON, RuZr, RuZrO or RuB.

5. The method of claim 1, wherein the surface of the capping layer is scanned using scanning electron microscopy.

6. The method of claim 1, wherein the height of the capping layer remaining in the damaged region is measured using atomic force microscopy.

7. The method of claim 1, wherein the image is analyzed by an image processor.

8. The method of claim 1, wherein the capping patch layer is deposited by electron-beam induced deposition.

9. The method of claim 8, wherein depositing the capping patch layer comprises:
providing a precursor gas to the capping layer; and
directing an electron beam toward the capping layer above the damaged region to induce deposition of the capping patch layer in the damaged region.

10. The method of claim 9, wherein the precursor gas comprises a ruthenium complex.

11. The method of claim 10, wherein the ruthenium complex has the following formula: 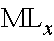
wherein:
M is Ru;
L is, at each occurrence, independently an acetylacetonate, alkylcyclopentadienyl, benzene, carbonyl, cyclopentadienyl, cyclyhexadiene, fluorinated amino alcohol, pentadienyl, pyrrolyl, trifluoroalkyl or halogen ligand, derivatives thereof or combinations thereof; and
x is an integer of 1 to 6.

12. The method of claim 11, wherein the ruthenium complex has one of the following structures: 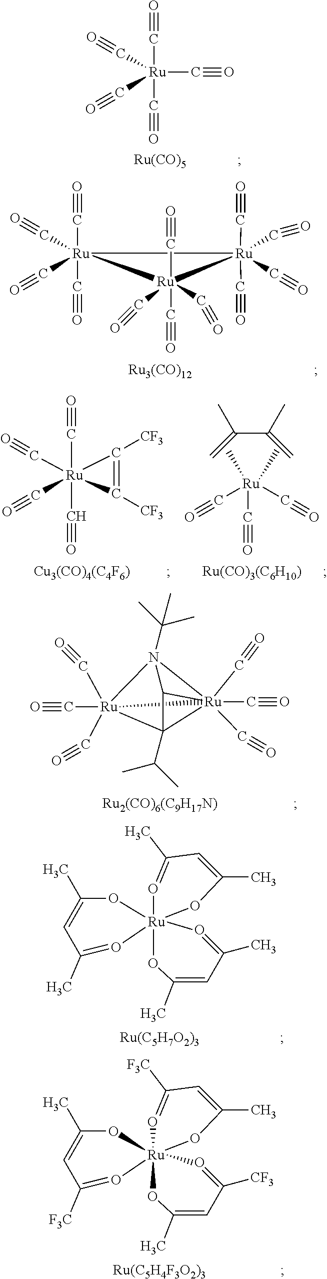 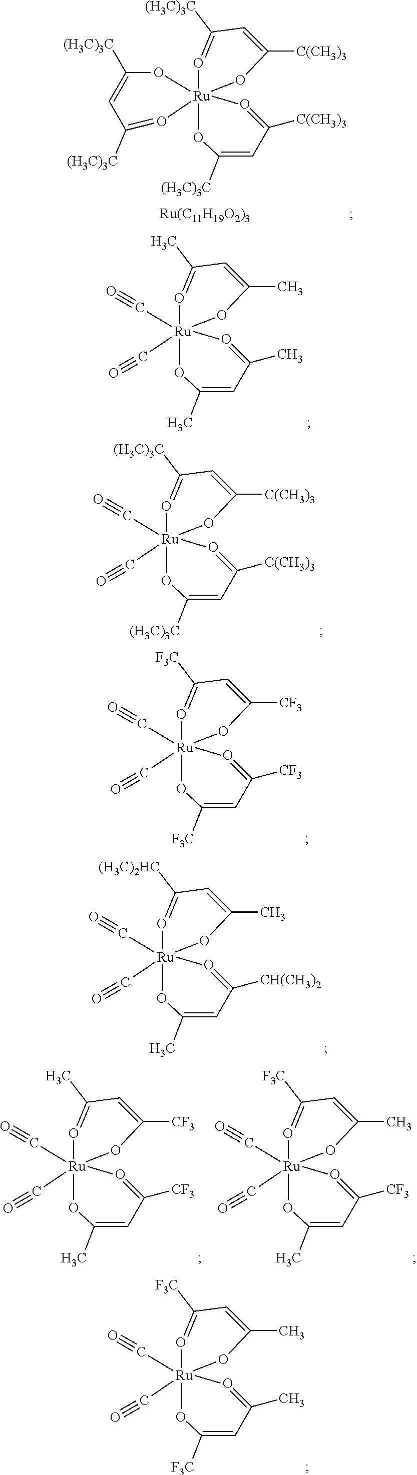 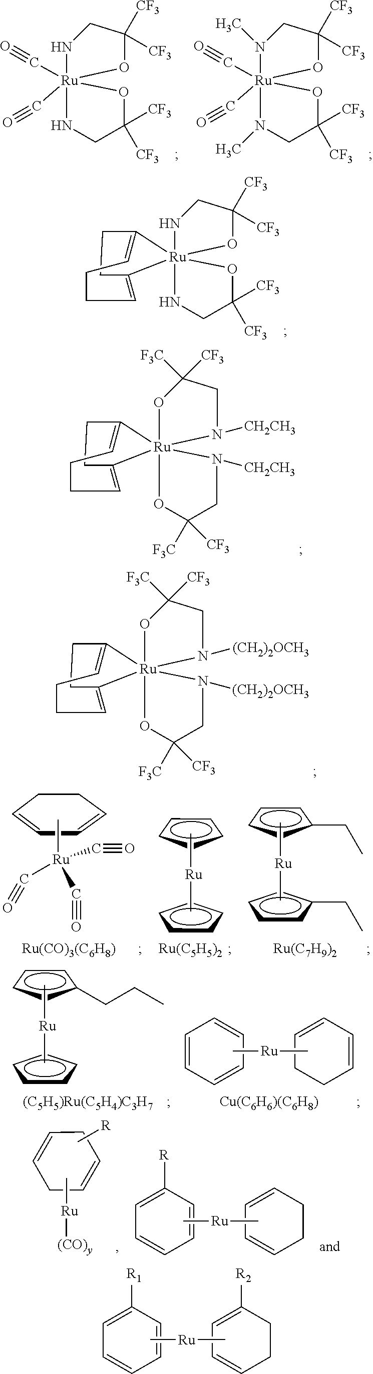
wherein:
R, R₁ and R₂ are each independently alkyl or alkoxy; and
y is an integer from 1 to 5.

13. A method, comprising:
obtaining an image of a surface of a capping layer of a lithography photomask by scanning the surface of the capping layer using scanning electron microscopy, the lithography photomask comprising:
a substrate;
a reflective multilayer stack over the substrate;
the capping layer over the reflective multilayer stack and comprising ruthenium (Ru), wherein the capping layer includes a damaged region where at least a portion of the capping layer is lost; and
a patterned absorber layer over the capping layer;
analyzing the image to identify a location, a length and a width of the damaged region of the capping layer using an imaging processor;
measuring a height of the capping layer remaining in the damaged region using atomic force microscopy;
determining a duration for refilling the damaged region based on the length and the width of the damaged region of the capping layer, and the height of the capping layer remaining in the damaged region; and
depositing a Ru-containing capping patch layer in the damaged region of the capping layer by supplying a Ru-containing precursor gas into a deposition chamber and directing an electron beam toward the capping layer above the damaged region.

14. The method of claim 13, a top surface of the Ru-containing capping patch layer is coplanar with a top surface of the capping layer in a non-damaged region.

15. The method of claim 13, wherein the Ru-containing precursor gas is supplied at a rate such that the deposition of the Ru-containing capping patch layer is completed within the duration.

16. The method of claim 15, wherein the rate for supplying the precursor gas into the deposition chamber ranges from 1 to 100,000 standard cubic centimeters per minute (sccm).

17. A method, comprising:
placing a lithography photomask in a scanning electron microscopy (SEM) tool, the lithography photomask comprising:
a substrate;
a reflective multilayer stack over the substrate;
a capping layer comprising ruthenium (Ru) over the reflective multilayer stack; and
a patterned absorber layer over the capping layer,
wherein the capping layer includes a damaged region having at least a portion of the capping layer being lost;
obtaining an SEM image of the capping layer;
recording a location of the damaged region of the capping layer;
placing the lithography photomask in an atomic force microscopy (AFM) tool;
using the AFM tool to measure a remaining thickness of the capping layer at the recorded location;
analyzing the SEM image to calculate an area of the damaged region of the capping layer;
calculating a deposition time that is required to fill the damaged region of the capping layer, based on the remaining thickness and the area of the damaged region;
placing the lithography photomask in the SEM tool;
injecting a Ru-containing precursor gas into the SEM tool; and
focusing an electron beam on the damaged region which causes deposition of a Ru-containing material in the damaged region to form a capping patch layer therein.

18. The method of claim 17, wherein the capping patch layer includes amorphous Ru or RuO₂.

19. The method of claim 17, wherein the location of the damaged region is recorded by coordinates in a grid based on distances away from edges of the SEM image.

20. The method of claim 17, wherein the Ru-containing precursor gas includes a ruthenium complex having one of the following structures: [chemical structure]
